(19) United States
(12) Patent Application Publication
(10) Pub. No.: US 2002/0140582 A1
(43) Pub. Date: Oct. 3, 2002

(54) Finger identifying keyboard

(75) Inventor: Sheng Ye, Beijing (CN)

Correspondence Address: IBM CORPORATION, PO BOX 12195, DEPT 9CCA, BLDG 002, RESEARCH TRIANGLE PARK, NC, 27709, US

(73) Assignee: International Business Machines Corporation, Armonk, NY (US)

(21) Appl. No.: 10/097,803

(22) Filed: Mar. 14, 2002

(30) Foreign Application Priority Data
Mar. 29, 2001 (CN) 01112131.9

(51) Int. Cl. H03M 11/00; H03K 17/94

(52) U.S. Cl. 341/22

(57) ABSTRACT

The present invention provides a finger-identifying keyboard, comprising a plurality of keys; a plurality of sensors wearable on the fingers, each sensor representing a different finger; a coding synthesizer used to identify simultaneously the keys and the fingers used to press the keys, to synthesize the coding and to generate the resultant input coding signal. The invention can effectively reduce the number of keys on the keyboard, thereby achieving the goal of reducing the size of the keyboard so as to be adapted to the requirements of various handheld devices.

### BACKGROUND OF THE INVENTION

1) Field of the Invention

The present invention relates to a finger-identifying keyboard, and more particularly relates to a finger-identifying keyboard that can reduce the number of keys on the keyboard and the size of the keyboard.

2) Prior Art

Data inputting is an indispensable function of various electronic equipments. Among the vast amount of inputting methods, keyboard-inputting method is still the leading one with regard to speed and accuracy. In the process of miniaturization of electronic equipment, the size of the inputting device is continuously decreasing.

In prior art, there are some limitations on the miniaturization of the keyboards. First, in order for the users to input conveniently with their own fingers, the size of the keys can not be too small. Too small a key will either make the users unable to use fingers to press the key or readily produce errors. Second, in order to input enough number of digits and alphabetic characters, it is necessary to have enough number of keys. Both of these two aspects limit the miniaturization progress of the keyboards.

U.S. Pat. No. 5,367,298 disclosed a keyboard, which, with reference to FIG. 1, reduces the number of keys to about one half of the number of keys of the standard keyboard, wherein each key is assigned to at least two characters. For example, “H”, “J”, “K”, “L” and ″″′ keys are assigned to “G”, “F”, “D”, “S” and “A” characters respectively according to their mirror positions. The characters are switched between each other by using the MODE key.

In the above configuration, the number of keys can be reduced. But the keyboard still has to have at least more than 20 keys for all the characters to be inputted. Hence, there is a limitation to further miniaturization of the keyboards.

### SUMMARY OF THE INVENTION

The present inventor has found through investigation that when people are using a keyboard, usually they are using different fingers to press different keys. If the fingers can be distinguished from each other, then the keystroke of the same key by different fingers can produce different combinations of characters, and produce different character output, thereby achieving the functions of a whole keyboard by using small number of keys.

Therefore, the object of the invention is to provide a finger-identifying keyboard that can effectively reduce the number of keys, thereby reducing the size of the keyboard.

According to the invention, a finger-identifying keyboard is provided, which includes:

a plurality of keys;

a plurality of sensors wearable on the fingers, each of which represents a different finger;

a coding synthesizer used to identify simultaneously the keys and the fingers used to press the keys, thereby synthesizing the coding to generate a final inputcoding signal.

The above-mentioned sensors can be a kind of contact sensors.

The above sensors can also be a kind of magnetic sensors.

The number of the above-mentioned keys is preferably 15.

The number of said sensors worn on the fingers is preferably 4.

The above design of the invention can effectively reduce the number of the keys of the keyboard, thereby achieving the goal of reducing the size of the keyboard. Since the method identifies the finger which presses the key, it has little influence on the inputting habit. For the handheld devices, the keyboard should be small enough to be easily carried around and in many cases only one hand is available for input. The finger-identifying keyboard can solve such a problem.

Further, the finger-identifying keyboard of the invention reduces the size of a keyboard without reducing the size of a key. It is especially suitable for data input in miniaturized and handheld devices. As it keeps the conventional inputting habit, it can be easily mastered. Due to the reduced number of keys, the number of electrical and mechanical components can be accordingly reduced while only a small number of electronic parts are added, therefore the cost will not exceed that of the conventional keyboard.

### BRIEF DESCRIPTION OF THE DRAWINGS

FIG. 1 is a schematic view of a prior art keyboard with reduced size.

FIG. 2 is an embodiment of a finger-identifying keyboard of the invention—both-hand keyboard layout example.

FIG. 3 is another embodiment of a finger-identifying keyboard of the invention—single-hand keyboard layout example.

FIG. 4 is a block diagram of the coding synthesizing function of a finger-identifying keyboard of the invention.

FIG. 5 is an embodiment of the particular electrical circuit of the coding synthesizing of the invention.

Below there will be a detailed description with reference to the accompanying drawings.

### DETAILED DESCRIPTION OF THE PREFERRED EMBODIMENT

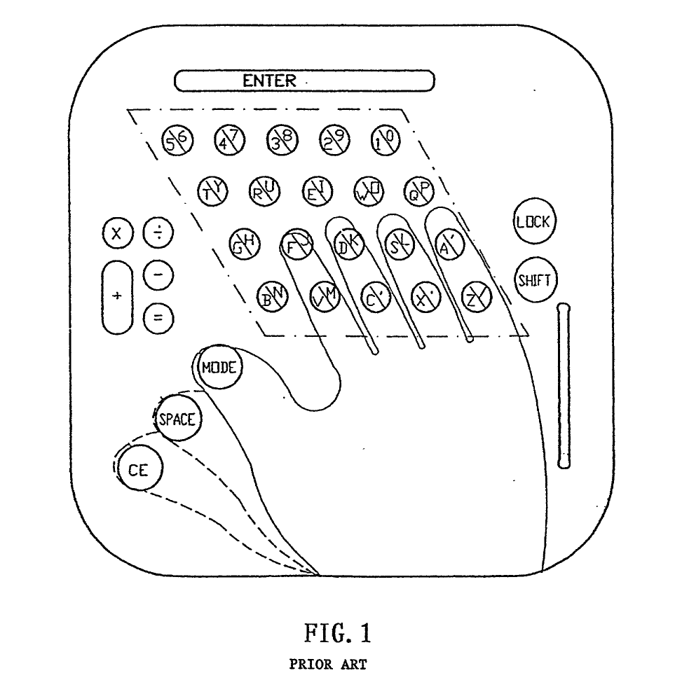

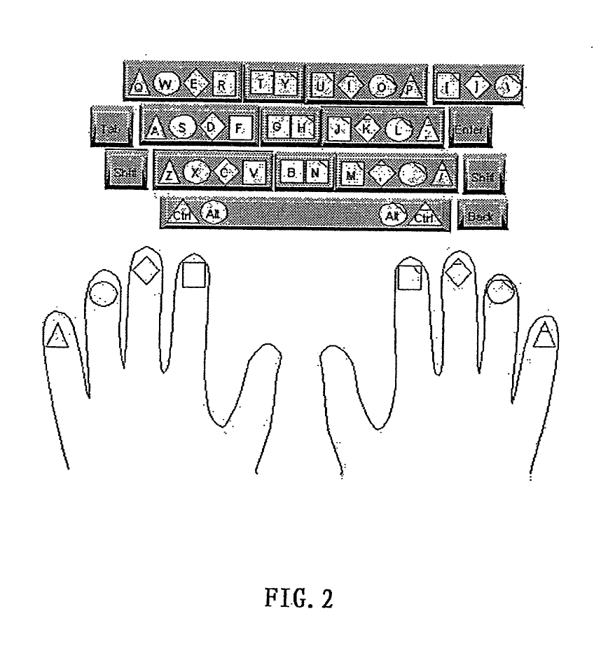

FIG. 1 is a schematic view of a prior art keyboard with reduced size, which has been previously mentioned. FIG. 2 is an embodiment of a finger-identifying keyboard of the invention, in which the layout of a both-hand keyboard is shown. In the figure, different shapes represent different characters actually produced by the keystroke of different fingers. As shown in the figure, the whole inputting device comprises a keyboard and a plurality of finger contacts or touching points. The function of the keyboard is the same as that of a conventional keyboard, while the finger contacts are used to distinguish the fingers that press the keys. Here only four fingers have the contacts, as conventionally the thumbs are only used for pressing the “space” key, thus, final coding can be produced directly for the space key. The implementation of the keyboard connection is the same as that of an ordinary keyboard, with the finger wearing the contacts for connection to the keyboard, and the coding synthesizing components placed inside the keyboard. During a keystroke, the signals from the keyboard and the finger-contacts are simultaneously sent into the coding synthesizing component. After the synthesizing operation, the actual coding is outputted. Hence the keyboard input interface may employ a standard keyboard interface.

Employing a finger-identifying keyboard reduces the number of the keys, thus requiring the change of the keyboard layout. For the both-hand keyboard, the keyboard layout can be the same as a conventional one, with the number of keys reduced, thereby reducing the area of the keyboard. For a foldable keyboard, it is easier to fold due to the small number of keys used. The users can readily accept and get used to it by using the conventional keyboard layout. As one key stands for more than one key, it is possible to increase the size or the length of a key appropriately. Here the space key, CTRL key and ALT key are combined into one. Usually a thumb is used to press the space key. When the space key is pressed without a contact, a space character is sent out. When the contact of the ring finger is activated at the same time, it means an ALT key. Similarly, when the contact of the little finger is activated at the same time, it means a CRTL key.

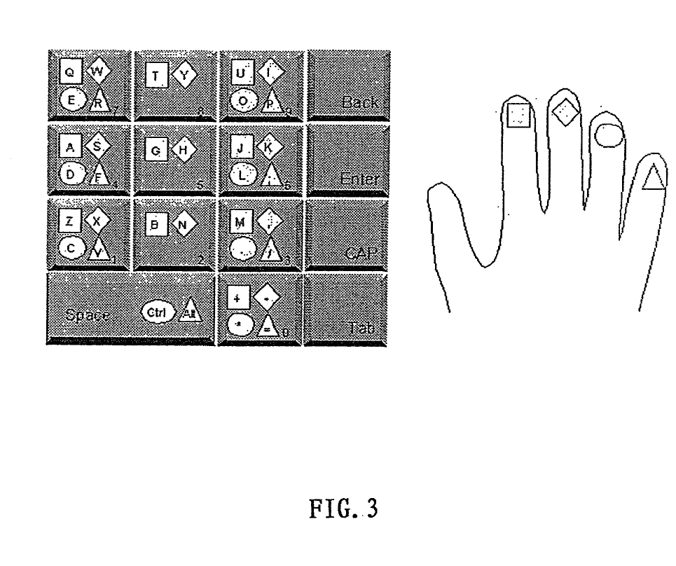

FIG. 3 is an example of the layout of a finger-identifying keyboard of another embodiment of the invention. This is a single-hand keyboard. In the figure different shapes represent different characters actually produced through keystroke by different fingers. Each key represents four letters and the space key represents “CTRL” and “Alt” keys. Four sensors worn on the fingers are used to distinguish the fingers. In such a way, each key is able to produce four kinds of combination. Hence only ten keys can produce 40 combinations, thereby easily implementing all the character inputting functions. Here, there is no need to use additional sensor for the thumbs, since it's only necessary to distinguish different fingers. Therefore, in the design each key may have its default meaning to be flexibly used in actual applications. For example, the digit keys can be added. The number of keys in the figure is 15, which can be increased or decreased as needed. For the single-hand keyboard, it is still based on the conventional keyboard. Changing the key positions will make it difficult for the users to remember. The use of the fingers conforms to the convention as much as possible, thereby letting the users quickly get used to such a configuration. Such a miniaturized keyboard layout can reduce the size of the keyboard to that of a PDA so that it can be used for the small handheld devices. In actual application, it may be the case that the left hand is used to hold the keyboard while the right hand is used to operate the keyboard. When only one hand is used for operation, it is difficult to use the SHIFT key, so here CAPS LOCK key is used. Subsidiary functions are used for the combined key functions, i.e. by successively pressing the corresponding keys to implement the combined key functions.

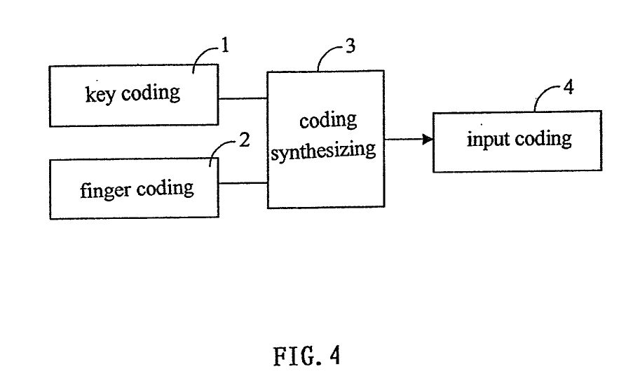

FIG. 4 is a block diagram of the coding synthesizing components of a finger-identifying keyboard of the invention. It generates input code by using coding synthesizing components to synthesize the key coding and the finger coding. The actual input operation consists of two parts: during a keystroke, the pressed key and the contact of the pressing finger produce their coding respectively, i.e. key coding 1 and finger coding 2. These two parts of coding are coding-synthesized 3 to form actual input coding 4. In actual application the time of a keystroke may be slightly different from the time when the contact of the finger is activated, thus requiring the coding synthesizing components being able to tolerate some time delay. However, the recovery time after the activation of the keystroke and keyboard should be shorter than this time delay. With respect to the speed of keystrokes by human beings, the operating speed of electric components is far higher than that of human beings, hence this requirement can be easily met.

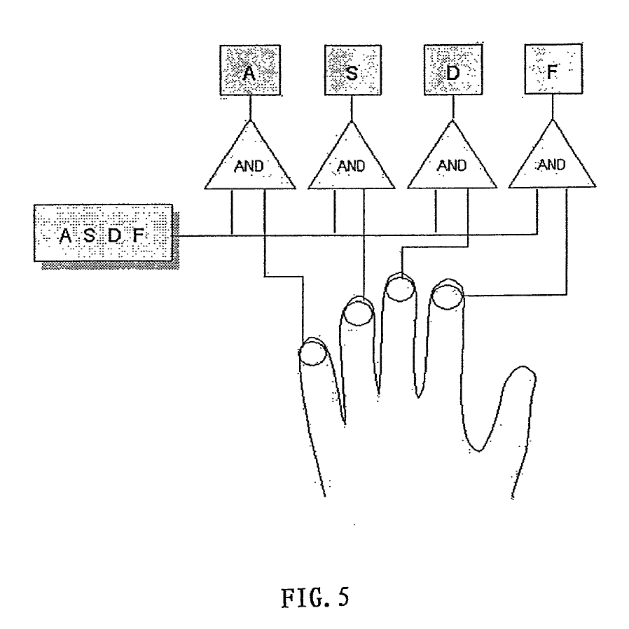

FIG. 5 is an embodiment of the particular electric circuit of the coding synthesizing of the invention. The coding synthesizing circuit can be implemented by using gate circuits, i.e. coding separation can be implemented by the “AND” operation of the keystroke and the sensor contact activation. As shown in the figure, the characters ASDF that are on the same key can be distinguished by identifying the fingers used. If the little finger is used to press the key, the contact of the sensor of the little finger will be activated, and the result of “AND” operation is a character A. Similarly, the keystroke of the middle finger will result in a character D. Here the fundamental principle of identification has been explained, the actual coding synthesizing and identification function can be realized by employing complicate electric circuits.

The implementation of the keyboard of the invention is basically identical to that of the conventional keyboard, with the contacts of the sensors worn on the fingers for connection to the keyboard. The contacts may be connected wirelessly, e.g. some magnetic materials may be used, as long as the fingers used to press the keys can be distinguished. The keyboard and the sensor contacts can use well-known prior art; the contacts can be implemented by using electricity conducting glue or thin-film switches. To make the finger feel comfortable, the pressure of the contacts should be as weak as possible, i.e. the contacts should be activated once a pressure is sensed such that the fingers will not have unpleasant feeling.

While the present invention has been described with reference to the details of the embodiments of the invention shown in the drawings, these details are not intended to limit the scope of the invention as claimed in the appended claims.

I claim:

1. A finger-identifying keyboard, comprising:
a plurality of keys;
a plurality of sensors wearable on the fingers, each sensor representing a different finger;
a coding synthesizer used to distinguish simultaneously the keys and the fingers used to press the keys, to synthesize -the coding and to generate the resultant input coding signal.

2. A finger-identifying keyboard according to claim 1, characterized in that said sensor is a kind of contact sensor.

3. A finger-identifying keyboard according to claim 1, characterized in that said sensor is a kind of magnetic sensor.

4. A finger-identifying keyboard according to claim 1, characterized in that the number of said keys is 15.

5. A finger-identifying keyboard according to claim 1, characterized in that the number of the sensors worn on the fingers is 4.

6. A keyboard including:
a plurality of keys wherein at least one key of said plurality of keys representing a plurality of different symbols with each symbol representing a different character; and
a synthesizer responsive to a first signal from the at least one key and a second signal from one of the symbols to generate a third signal representative of a particular keystroke.

7. The keyboard of claim 6 wherein the first signal is generated by a finger pressing said at least one key.

8. The keyboard of claim 7 wherein the second signal is provided by a sensor carried on the finger and simultaneously activated when the at least one key is pressed.

9. The keyboard of claim 6 wherein the synthesizer includes at least one AND gate receiving the first signal and second signal and outputting the third signal.

10. A method to generate keystrokes comprising the acts of:
providing a keyboard having a plurality of keys with at least one key representing a plurality of characters;
receiving in a synthesizer a first signal representing activation of said at least one key and a second signal representing activation of one of the plurality of characters; and
generating from said synthesizer a third signal representing a predetermined keystroke.

11. The method of claim 10 wherein the second signal is generated from activation of a sensor carried on a finger.
